(19) United States
(12) Patent Application Publication
(10) Pub. No.: US 2026/0190770 A1
(43) Pub. Date: Jul. 2, 2026

(54) DISPLAY DEVICE

(71) Applicant: LG Display Co., Ltd., Seoul (KR)

(72) Inventor: Jaehyuk LEE, Paju-si (KR)

(73) Assignee: LG Display Co., Ltd., Seoul (KR)

(21) Appl. No.: 19/431,772

(22) Filed: Dec. 23, 2025

(30) Foreign Application Priority Data
Dec. 31, 2024 (KR) 10-2024-0202611

(51) Int. Cl. H10K 59/80

(52) U.S. Cl. CPC H10K 59/8722; H10K 59/873; H10K 59/8794

(57) ABSTRACT

A display device can include a display part having a display area and a non-display area, a sealing member disposed over the display part, a reinforcing substrate disposed over the sealing member, and an auxiliary film disposed between the sealing member and the reinforcement substrate in the non-display area. The auxiliary film can be made of a material having a smaller coefficient of thermal expansion than that of the reinforcement substrate, and can have an uneven pattern on a lower surface of the auxiliary film.

### CROSS-REFERENCE TO RELATED APPLICATIONS

This application claims priority to Korean Patent Application No. 10-2024-0202611 filed on December 31, 2024, in the Korean Intellectual Property Office, the entire disclosure of which is hereby expressly incorporated by reference.

### BACKGROUND

### Field

The present disclosure relates to a display device.

### Discussion of the Related Art

Currently, as the world enters a full-fledged information era, the field of display devices that visually display electrical information signals is rapidly developing, and research continues to improve the performances of various display devices, including thinning, weight reduction, and low power consumption.

Representative display devices include a liquid crystal display (LCD), an electro-wetting display (EWD), and an organic light emitting display (OLED).

Among these display devices, an electroluminescent display device including an organic light emitting display device is a self-emitting display device and does not require a separate light source unlike a liquid crystal display device, and thus can be manufactured to have a light weight and a small thickness. In addition, the electroluminescent display device is advantageous not only in terms of power consumption because the electroluminescent display device operates at a low voltage, but also in terms of color implementation, a response speed, a viewing angle, and a contrast ratio (CR), so it is expected to be utilized in various fields.

A small-sized display panel used in a mobile device and a portable device has a small area of the display panel so that heat generation in an element is rapidly emitted and there is less problem of bonding. However, in a large-sized display panel used in a monitor, tablet, or television receiver, the area of the display panel is large, so that an encapsulation structure for an optimal heat dissipation effect and bonding force is required.

In addition, in order to compensate for insufficient rigidity, the electroluminescent display device can further include a separate inner plate on the encapsulation substrate. In this case, it is necessary to secure a space for disposing a separate inner plate, and there can be a problem in that there is a limitation in slimming and lightening of the electroluminescent display device due to the weight of the inner plate. In addition, there can be a limitation in that a vertical space is generated by an air gap generated between the encapsulation substrate and the inner plate as much as the thickness of the adhesive tape disposed to adhere the encapsulation substrate and the inner plate, thereby deteriorating heat dissipation performance.

### SUMMARY OF THE DISCLOSURE

An object to be achieved by the present disclosure is to provide a display device including an encapsulation part having a new structure in which rigidity of a display panel is increased and a heat dissipation effect is improved.

Another object to be achieved by the present disclosure is to provide a display device capable of preventing a bubble defect generated at an interface with a substrate due to expansion and contraction of a reinforcing substrate having a high thermal expansion coefficient in a high temperature and high humidity environment.

Another object to be achieved by the present disclosure is to provide a display device, which can address the limitations and disadvantages associated with the related art.

Objects of the present disclosure are not limited to the above-mentioned objects, and other objects, which are not mentioned above, can be clearly understood by those skilled in the art from the following descriptions.

In order to achieve the above-mentioned objects, a display device according to an example embodiment of the present disclosure includes a display part including a display area and a non-display area, a sealing member disposed over the display part, a reinforcement substrate disposed over the sealing member, and an auxiliary film disposed between the sealing member and the reinforcement substrate in the non-display area and made of a material having a smaller coefficient of thermal expansion than that of the reinforcement substrate, and having an uneven pattern on a lower surface of the auxiliary film.

Other detailed matters of the embodiments of the present disclosure are included in the detailed description and the drawings.

According to aspects of the present disclosure, an auxiliary film having a low coefficient of thermal expansion is inserted into a bezel area where diagonal bubbles can be generated due to expansion and contraction of a reinforcement substrate having a high coefficient of thermal expansion, thereby suppressing deformation and minimizing interface effects even under high temperature and high humidity environment. Accordingly, the generation of bubbles can be effectively controlled to reduce the rate of moisture penetration through the bubbles, thereby providing improved long-term durability and reliability.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a plan view schematically illustrating a display device according to a first embodiment of the present disclosure.

FIG. 2 is an example of a cross-sectional view taken along the line I-I' of FIG. 1.

FIG. 3 is a cross-sectional view illustrating a sub pixel of a display device according to the first embodiment of the present disclosure.

FIG. 4 is a cross-sectional view illustrating a display device according to a second embodiment of the present disclosure.

FIG. 5 is a cross-sectional view illustrating a display device according to a third embodiment of the present disclosure.

FIG. 6 is a cross-sectional view illustrating a display device according to a fourth embodiment of the present disclosure.

FIG. 7 is a cross-sectional view illustrating a display device according to a fifth embodiment of the present disclosure.

FIG. 8 is a cross-sectional view illustrating a display device according to a sixth embodiment of the present disclosure.

FIG. 9 is a plan view schematically illustrating a display device according to a seventh embodiment of the present disclosure.

FIG. 10 is an example of a cross-sectional view taken along the line II-II' of FIG. 9.

FIG. 11 is a plan view schematically illustrating a display device according to an eighth embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “over,” “above”, “below”, “under”, and “next”, etc., one or more parts can be positioned between the two parts unless the terms are used with the term “immediately” or “directly”.

When an element or layer is disposed “on” or “over” another element or layer, another layer or another element can be interposed directly on the other element or therebetween.

Although the terms such as “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure.

Further, the term “can” fully encompasses all the meanings and coverages of the term “may” and vice versa.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, example embodiments of the present disclosure will be described in detail with reference to accompanying drawings. All the components of each display device/apparatus according to all embodiments of the present disclosure are operatively coupled and configured.

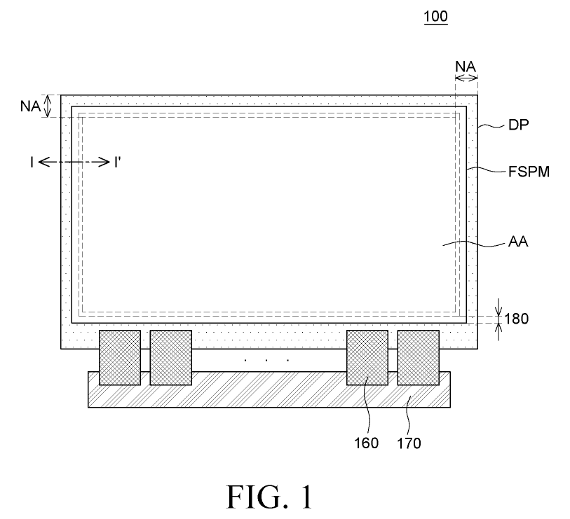

FIG. 1 is a plan view schematically illustrating a display device according to a first embodiment of the present disclosure.

Referring to FIG. 1, for example, a display device 100 according to the first example embodiment of the present disclosure can include a display part DP, an encapsulation part FSPM, a flexible film 160, and a printed circuit board 170.

The display part DP can be a panel for displaying an image to a user.

The display part DP can include a display element for displaying an image, a driving element for driving the display element, and wirings for transmitting various signals to the display element and the driving element. The display element can be defined in different ways depending on the type of the display part DP. For example, when the display part DP is configured as an organic light emitting display panel, the display element can be a light emitting element including an anode, an organic layer, and a cathode. For example, when the display part DP is configured as a liquid crystal display panel, the display element can be a liquid crystal display element.

Hereinafter, it is assumed that the display part DP is configured by an organic light emitting display panel, but it is not limited thereto.

The display part DP can include a display area AA (or active area) and a non-display area NA (or non-active area). The display area AA is an area in which images are displayed on the display part DP.

In the display area AA, a plurality of sub-pixels constituting a plurality of pixels and a circuit for driving the plurality of sub-pixels can be disposed. The plurality of sub-pixels is minimum units constituting the display area AA, and a display element can be disposed in each of the plurality of sub-pixels, and the plurality of sub-pixels can constitute a pixel. For example, in each of the plurality of sub-pixels, a light emitting element including an anode, an organic layer, and a cathode can be disposed, and is not limited thereto. Further, a circuit for driving the plurality of sub pixels can include a driving element, a wiring, and the like. For example, the circuit can be made of a thin film transistor, a storage capacitor, a gate line, a data line, or the like, and is not limited thereto.

The non-display area NA is an area where an image is not displayed.

FIG. 1 illustrates that the non-display area NA encloses the display area AA having a rectangular shape. However, the shapes and arrangements of the display area AA and the non-display area NA are not limited to the example illustrated in FIG. 1.

For example, the display area AA and the non-display area NA can have shapes suitable for the design of an electronic device equipped with the display device 100. For example, an example shape of the display area AA can be a pentagon, a hexagon, a circle, or an oval.

In the non-display area NA, various wirings and circuits for driving the light emitting element of the display area AA can be disposed. For example, in the non-display area NA, a link line for transmitting signals to the plurality of sub-pixels and circuits of the display area AA or a driving IC such as a gate driver IC or a data driver IC can be disposed, but it is not limited thereto.

For example, the display device 100 can include various additional elements for generating various signals or driving the pixel in the display area AA. For example, the additional elements for driving the pixels can include an inverter circuit, a multiplexer, an electrostatic discharge (ESD) circuit, and the like. The display device 100 can also include additional elements related to functions other than driving of the pixel. For example, the display device 100 can further include additional elements that provide a touch sensing function, a user authentication function (e.g., fingerprint recognition), a multi-level pressure sensing function, and a tactile feedback function. The above-mentioned additional elements can be located in an external circuit connected to the non-display area NA and/or a connection interface.

The flexible film 160 is a film in which various components are disposed on a base film having flexibility. For example, the flexible film 160 is a film for supplying signals to the plurality of sub-pixels and circuits of the display area AA and can be electrically connected to the display part DP. The flexible film 160 is disposed at one end of the display part DP to supply a power voltage, a data voltage, etc. to the plurality of sub-pixels and circuits of the display area AA. Accordingly, the number of flexible films 160 can be variously modified depending on the design, and is not limited thereto.

For example, a driving IC such as a gate driver IC and a data driver IC can be disposed on the flexible film 160. The driving IC is a component that processes data for displaying an image and a driving signal for processing the data. The driving IC can be disposed by a chip on glass (COG), a chip on film (COF), a tape carrier package (TCP) or the like depending on a mounting method.

The printed circuit board 170 can be disposed at one end of the flexible film 160 to be connected to the flexible film 160. For example, the printed circuit board 170 is a component that supplies a signal to the driving IC. The printed circuit board 170 can supply various signals such as a driving signal and a data signal to the driving IC. For example, a data driver for generating data signals can be mounted on the printed circuit board 170, and the generated data signal can be supplied to sub-pixels and circuits of the display part DP through the plurality of flexible films 160.

Meanwhile, an encapsulation part FSPM can be disposed on the display part DP.

The encapsulation part FSPM can include a sealing member and a reinforcing substrate.

When the encapsulation structure of the multilayer structure including the reinforcing substrate is introduced as described above, rigidity and heat dissipation effects can be sufficiently secured. However, when a plastic polymer such as polyethylene terephthalate (PET) is used as the reinforcing substrate, bubbles are generated in an oblique line shape in a high temperature and high humidity environment due to the difference in thermal expansion coefficient between the reinforcing substrate and the substrate of the display part DP, and moisture can penetrate through the bubbles, thereby reducing reliability. For reference, air bubbles in an oblique line shape are generated on the bonding surface between the substrate of the display part DP and the sealing member of the encapsulation part FSPM, and are generated over time in a high-temperature environment due to a difference in thermal expansion coefficient between the substrate and the sealing member, appearing diagonally in the bezel area. In a high-temperature and high-humidity environment, moisture introduced from the outside penetrates through the voids at the interface between the substrate and the sealing member, thereby adversely affecting the reliability of the display panel.

Accordingly, according to the present disclosure, an auxiliary film 180 having a low coefficient of thermal expansion is inserted into a bezel area where bubbles can be generated due to expansion and contraction of a reinforcing substrate having a high coefficient of thermal expansion (CTE), thereby suppressing deformation and minimizing interface effects due to expansion and contraction of the reinforcing substrate even under high temperature and high humidity environments.

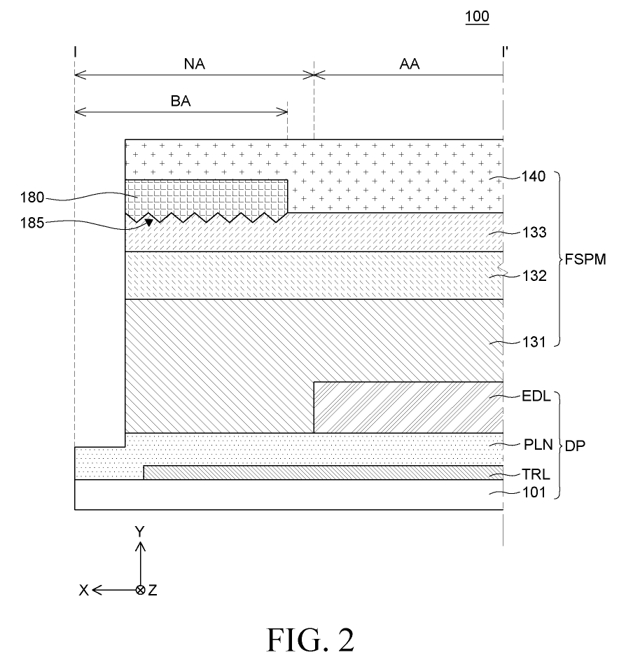

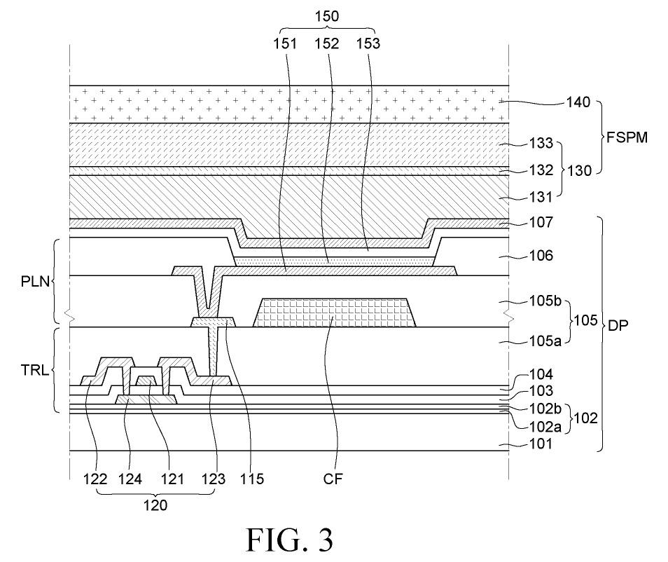

Hereinafter, the display part DP and the encapsulation part FSPM of the present disclosure will be described in detail with reference to FIGS. 2 and 3.

FIG. 2 is a cross-sectional view taken along the line I-I' of FIG. 1.

FIG. 3 is a cross-sectional view illustrating a sub pixel of a display device according to the first embodiment of the present disclosure.

Particularly, FIG. 2 illustrates a cross-section of one side of the display device 100 as an example. In FIG. 2, for the convenience of description, a detailed configuration of the transistor layer TRL and the light emitting element layer EDL is omitted. FIG. 3 is a cross-sectional view of one sub-pixel in the display part DP of the first embodiment of the present disclosure.

Referring to FIGS. 2 and 3, the transistor layer TRL can be disposed over the substrate 101.

For example, the substrate 101 can be a glass or plastic substrate. When the substrate 101 is the plastic substrate, a polyimide-based or polycarbonate-based material can be used to have flexibility. In particular, polyimide can be applied to high-temperature processes and is a material capable of coating, so it is widely used as the plastic substrate.

A buffer film 102 can be disposed on the substrate 101.

The buffer film 102 is a layer for protecting various electrodes and wirings from impurities such as alkali ions flowing out from the substrate 101 or the underlying layers. The buffer film 102 can have a multilayer structure including a first buffer film 102a and a second buffer film 102b, and is not limited thereto. The buffer film 102 can be made of silicon oxide (SiOx), silicon nitride (SiNx), or a multi-layer thereof.

Further, the buffer film 102 can delay the diffusion of moisture and/or oxygen permeating the substrate 101. The buffer film 102 can include a multi-buffer and/or an active buffer. The active buffer protects the active layer 124 which is formed of a semiconductor of the driving element 120 and can perform a function of blocking various types of impurities introduced from the substrate 101. The active buffer can be formed of amorphous silicon (a-Si) or the like.

The driving element 120 can be disposed over the buffer film 102.

For example, the driving element 120 can include an active layer 124, a gate electrode 121, a source electrode 122, and a drain electrode 123, and is electrically connected to the light emitting element 150 through a connection electrode 115 to transmit a current or a signal to the light emitting element 150.

The active layer 124 can be disposed on the buffer film 102. The active layer 124 can be made of polysilicon (p-Si), and in this case, a predetermined region can be doped with impurities. Further, the active layer 124 can be made of amorphous silicon (a-Si) and can be made of various organic semiconductor materials such as pentacene. Further, the active layer 124 can be made of an oxide semiconductor.

A gate insulating layer 103 can be disposed on the active layer 124.

The gate insulating layer 103 can be formed of an insulating inorganic material such as silicon oxide (SiOx) or silicon nitride (SiNx), or an insulating organic material.

The gate electrode 121 can be disposed on the gate insulating layer 103.

The gate electrode 121 can be made of various conductive materials, for example, nickel (Ni), chromium (Cr), magnesium (Mg), aluminum (Al), molybdenum (Mo), tungsten (W), gold (Au), or an alloy thereof.

An interlayer insulating layer 104 can be disposed on the gate electrode 121.

The interlayer insulating layer 104 can be formed of an insulating inorganic material such as silicon oxide (SiOx) or silicon nitride (SiNx), or an insulating organic material.

A contact hole, through which the source region and the drain region of the active layer 124 are exposed, can be formed by selectively removing the gate insulating layer 103 and the interlayer insulating layer 104.

The source electrode 122 and the drain electrode 123 can be disposed on the interlayer insulating film 104.

The source electrode 122 and the drain electrode 123 can be formed of various conductive materials, such as nickel (Ni), chromium (Cr), magnesium (Mg), aluminum (Al), molybdenum (Mo), tungsten (W), gold (Au), or an alloy thereof.

The source electrode 122 and the drain electrode 123 can be electrically connected to the source region and the drain region, respectively.

If necessary, an additional protective film made of an inorganic insulating material can be formed to cover the source electrode 122 and the drain electrode 123.

The planarization layer PLN can be disposed over the transistor layer TRL configured as described above.

For example, the planarization film 105 can be disposed on the driving element 120.

The planarization film 105 can have a multilayer structure including at least two layers. For example, the planarization film 105 can include a first planarization film 105a and a second planarization film 105b. The first planarization film 105a can be disposed to cover the driving element 120, and can be disposed to expose parts of the source electrode 122 and the drain electrode 123 of the driving element 120.

The planarization film 105 can extend to the non-display area NA. The planarization film 105 can have a thickness of about 2 μm, and is not limited thereto.

The planarization film 105 can be an overcoat layer, and is not limited thereto.

Meanwhile, the connection electrode 115 for electrically connecting the drain electrode 123 of the driving element 120 and the light emitting element 150 can be disposed on the first planarization film 105a. In addition, referring to FIG. 3, various metal layers serving as wiring/electrodes such as data wiring or signal wiring can be disposed on the first planarization film 105a.

In addition, a color filter CF can be disposed on the first planarization film 105a, and is not limited thereto, and the color filter CF can be deleted depending on the type of the light emitting element 150.

The color filter CF of each sub-pixel can have any one of red, green, and blue colors. In addition, in the case of a sub-pixel in which white is implemented, the color filter CF may not be disposed. The arrangement of red, green, and blue can be variously formed, and a black matrix capable of absorbing external light can be provided between the color filters CF.

In the case of the bottom emission type, the color filter CF can be located below the anode 151.

Further, a second planarization film 105b can be disposed on the first planarization film 105a and the connection electrode 115.

As described above, the fact that the planarization film 105 is formed of two layers in the display part DP according to the first example embodiment of the present disclosure is due to the increased number of signal lines resulting from the high resolution design of the display part DP. Since it is difficult to place all wirings on a single layer while maintaining the minimum spacing, an additional layer is introduced. The addition of this second planarization film 105bprovides extra space for wiring arrangement, thereby facilitating the design of wiring and electrode layouts. Further, when the multilayer planarization film 105 is made of a dielectric material, it can also serve to form capacitance between the metal layers.

In this case, the second planarization film 105b can be formed to expose a part of the connection electrode 115, and the drain electrode 123 of the driving element 120 and the anode 151 of the light emitting element 150 can be electrically connected by the connection electrode 115.

The light emitting element layer EDL can be disposed over the planarization layer PLN configured as described above.

For example, the light emitting element layer EDL can be disposed in the display area AA.

For example, the light emitting element 150 can be configured such that the anode 151, the plurality of organic layers 152, and the cathode 153 are sequentially disposed.

For example, the light emitting element 150 can include the anode 151 disposed on the second planarization film 105b, the organic layer 152 disposed on the anode 151, and the cathode 153 disposed on the organic layer 152.

The electroluminescent display device can be implemented in a top emission method or a bottom emission method depending on the emission direction. In the top emission type, a reflective layer made of an opaque conductive material having a high reflectance, for example, silver (Ag), aluminum (Al), gold (Au), molybdenum (Mo), tungsten (W), chromium (Cr), or an alloy thereof can be added under the anode 151 so that light emitted from the organic layer 152 is reflected by the anode 151 and directed upward, for example, in the direction of the cathode 153. On the other hand, in the case of the bottom emission type, the anode 151 can be formed of only a transparent conductive material, such as indium tin oxide (ITO), indium zinc oxide (IZO), indium gallium zinc oxide (IGZO). Hereinafter, the description will be made on the assumption that the display device 100 of the present disclosure is the bottom emission type.

A bank 106 can be disposed on the planarization film 105 in the remaining area excluding an emission area.

For example, the bank 106 can have a bank hole which exposes the anode 151 corresponding to the emission area. The bank 106 can be made of an inorganic insulating material such as silicon nitride (SiNx) or silicon oxide (SiOx), or an organic insulating material such as BCB, acrylic resin, or imide resin.

The bank 106 can partially extend to the non-display area NA.

The bank 106 can have a thickness of about 1 μm, and is not limited thereto.

The organic layer 152 can be disposed on the anode 151 exposed by the bank 106. The organic layer 152 can include a light emitting layer, an electron injection layer, an electron transport layer, a hole transport layer, a hole injection layer, etc.

The organic layer 152 can partially extend to the non-display area NA.

The cathode 153 can be disposed on the organic layer 152.

In the case of the top emission type, the cathode 153 can include a transparent conductive material. For example, the cathode 153 can be formed of indium tin oxide (ITO), indium zinc oxide (IZO), indium gallium zinc oxide (IGZO), or the like. In the case of the bottom emission type, the cathode 153 can include any one of a group formed of a metal material such as gold (Au), silver (Ag), aluminum (Al), molybdenum (Mo), magnesium (Mg), palladium (Pd), copper (Cu) or an alloy thereof. Alternatively, the cathode 153 can be configured by laminating layers made of a transparent conductive material such as indium tin oxide (ITO), indium zinc oxide (IZO), indium gallium zinc oxide (IGZO), and layers made of a metal material such as gold (Au), silver (Ag) aluminum (Al), molybdenum (Mo), magnesium (Mg), palladium (Pd), copper (Cu), or an alloy thereof, and is not limited thereto.

The cathode 153 can extend to the non-display area NA.

A capping layer 107 made of a material having a high refractive index and a high light absorption rate can be disposed over the light emitting element 150 to reduce diffused reflection of external light.

For example, the capping layer 107 can be an organic material layer made of an organic material, and can be omitted if necessary.

The capping layer 107 can extend to the non-display area NA.

The encapsulation part FSPM can be disposed on the light emitting element layer EDL configured as described above.

The encapsulation part FSPM of the multilayer structure composed of the sealing member 130 and the reinforcement substrate 140 can be disposed over the capping layer 107.

As described above, according to the present disclosure, the encapsulation part FSPM of the multilayer structure, which includes the sealing member 130 capable of fixing the relatively thick reinforcing substrate 140 while removing the separate inner plate and preventing process defects can be applied.

The sealing member 130 of the present disclosure can include a first adhesive layer 131 facing the substrate 101, a second adhesive layer 133 facing the reinforcing substrate 140, and a metal layer 132 disposed between the first adhesive layer 131 and the second adhesive layer 133.

Each of the first adhesive layer 131 and the second adhesive layer 133 can be made of a polymer material having adhesiveness. For example, the first adhesive layer 131 can be made of any one of olefin-based, epoxy-based, urethane (or urea)-based, and acrylate-based polymer materials. Further, the second adhesive layer 133 can be made of any one of olefin-based, epoxy-based, acrylate-based, urethane-based, amine-based, phenol-based, and acid anhydride-based polymer materials that do not contain a carboxyl group. Further, for example, the second adhesive layer 133 can be formed of a polymer material in which a carboxyl group is not included to ensure the film uniformity and prevent corrosion of the metal layer 132.

For heat dissipation of the substrate 101, at least the first adhesive layer 131 of the first and second adhesive layers 131 and 133 can be formed of a mixture including an adhesive polymer material and particles of a metal material. For example, the particles of the metal material can be powder made of nickel (Ni). The first adhesive layer 131 in direct contact with the substrate 101 is composed of a mixture including an adhesive polymer material and particles of a metal material, so that the first adhesive layer 131 can have higher thermal conductivity than the adhesive polymer material.

For example, the second adhesive layer 133 can also be formed of a mixture including an adhesive polymer material and particles of a metal material, and can have higher thermal conductivity than the adhesive polymer material.

In this way, the driving heat generated from the substrate 101 can be more efficiently discharged through the sealing member 130, thereby enhancing the heat dissipation effect on the substrate 101.

In order to prevent moisture permeation into the light emitting element layer EDL, the first adhesive layer 131 may, for example, be formed of a mixture further including a hygroscopic inorganic filler.

For example, the hygroscopic inorganic filler can be at least one of barium oxide (BaO), calcium oxide (CaO), and magnesium oxide (MgO).

Unlike the first adhesive layer 131, the second adhesive layer 133 is not in contact with the light emitting element layer EDL; therefore, it is not necessary to include an inorganic filler for preventing moisture permeation of the light emitting element layer EDL. Accordingly, the second adhesive layer 133 does not include a hygroscopic inorganic filler, and can include only an adhesive polymer material and particles of a metal material. In this way, since the amount of the relatively expensive hygroscopic inorganic filler injected into the sealing member 130 can be reduced, thereby reducing manufacturing costs.

Further, since the hygroscopic inorganic filler is not included, the mixing ratio of the polymer material included in the second adhesive layer 133 can be increased compared to the first adhesive layer 131, so that the adhesiveness of the second adhesive layer 133 can be improved compared to the adhesiveness of the first adhesive layer 131. Accordingly, the fixing of the reinforcement substrate 140 on the second adhesive layer 133 can be made more rigid, thereby further improving the reliability of the bonding force between the substrate 101 and the reinforcement substrate 140.

The thickness of each of the first and second adhesive layers 131 and 133 can be limited to a threshold thickness or less at which process defects are prevented. Further, for example, the sum of the thicknesses of the first and second adhesive layers 131 and 133 can be limited to a critical thickness or more capable of securing reliability for fixing the reinforcing substrate 140.

The metal layer 132 can be made of a thin-film metal material.

For example, the metal layer 132 can include a metal material such as Al, Cu, Sn, Ag, Fe, Zn and the like.

For example, each of the first and second adhesive layers 131 and 133 includes a polymer material having adhesiveness, and the metal layer 132 having a relatively hard material is disposed between the first adhesive layer 131 and the second adhesive layer 133 to bond the first adhesive layer 131 and the second adhesive layer 133 to one surface and the other surface of the metal layer 132, respectively, thereby improving the bonding strength.

For example, the thickness of the metal layer 132 can be limited to a value smaller than the thickness of the first adhesive layer 131 in order to minimize an increase in the thickness of the sealing member 130 caused by the metal layer 132.

For example, the reinforcement substrate 140 can be made of any one of materials such as glass or a plastic polymer, for example, PET.

In this case, the sealing member 130 and the reinforcement substrate 140 can extend to the non-display area NA so as to cover a part of the planarization layer PLN.

As described above, according to the present disclosure, by introducing an encapsulation structure of a multilayer structure including a relatively thick reinforcing substrate 140, it is possible to sufficiently secure rigidity and heat dissipation effects. However, when the encapsulation structure of such a multilayer structure is applied, diagonal shaped bubbles are generated at the interface with the substrate 101 due to expansion and contraction of the relatively thick reinforcing substrate 140 having a high thermal expansion coefficient in high-temperature and high-humidity environments. In this way, reliability can be deteriorated due to the ingress of moisture through these diagonal bubbles caused by the difference in thermal expansion coefficient between components.

Accordingly, the first embodiment of the present disclosure is characterized in that the deformation is suppressed by inserting the auxiliary film 180, having a low coefficient of thermal expansion, into the bezel area BA where diagonal bubbles are generated due to the expansion and contraction of the reinforcing substrate 140, which has a high coefficient of thermal expansion. Since a diagonal defect caused by the difference in thermal expansion coefficient between the substrate 101 and the sealing member 130 occurs in the bezel area BA, which is an outer part of the display area AA that displays a screen, the auxiliary film 180 can be disposed in the bezel area BA. Moreover, as the area increases, the effect of defects on the size can become more significant, so that a pattern can be inserted in a matrix form within a frame shape.

For example, the auxiliary film 180 can be disposed between the reinforcement substrate 140 and the second adhesive layer 133. The auxiliary film 180 can have a rectangular frame shape along the edge of the non-display area NA, and is not limited thereto.

The auxiliary film 180 can be formed of a film such as silicon having a low coefficient of thermal expansion. For example, when the reinforcement substrate 140 having a thickness of 125 μm is formed of PET having a CTE of 70 ppm, the difference in thermal expansion coefficient with the substrate 101 having a CTE of 3.5 ppm and a thickness of 500 μm becomes large. Therefore, it is possible to suppress expansion and contraction of the reinforcement substrate 140 in a high temperature and high humidity environment by inserting the auxiliary film 180 made of silicon having a thickness of 4.2 ppm and 30 μm between the reinforcement substrate 140 and the second adhesive layer 133. However, the material of the auxiliary film 180 of the present disclosure is not limited to silicon and can be applied as long as it is a material similar to the CTE of the substrate 101, and can be used as long as it has a CTE of 10 ppm or less such as tungsten (4.59 ppm), molybdenum (5.43 ppm), titanium (8.35 ppm), platinum (9.0 ppm).

Further, the auxiliary film 180 can include a material having a coefficient of thermal expansion smaller than that of the reinforcement substrate 140.

Among them, titanium has an advantage of being able to trap hydrogen (H) generated from the sealing member 130, thereby partially controlling defects caused by hydrogen.

Further, for example, the auxiliary film 180 can include the uneven pattern (or concave-convex pattern) 185 on the lower surface thereof in order to enhance interface adhesion. The uneven pattern 185 can be formed by configured by repeating concave or convex portions in a triangular shape, and is not limited thereto.

The uneven pattern 185 can be disposed side by side in one direction. For example, in a high temperature and high humidity environment, the reinforcement substrate 140 expands to the outside and contracts to the inside. To suppress this, the uneven pattern 185 can be disposed in a direction perpendicular to the expansion and contraction direction of the reinforcement substrate 140. For example, in FIG. 2, when the reinforcement substrate 140 expands in the X-axis direction, the uneven pattern 185 can be disposed side by side in the Z-axis direction. In this case, on the left and right sides of the display part DP, the uneven pattern 185 can be disposed in a direction parallel to the data line, and on the upper and lower sides of the display part DP, the uneven pattern 185 can be disposed in a direction parallel to the gate line. However, the present disclosure is not limited thereto, and the uneven pattern 185 can be disposed in a zigzag shape in one direction. As shown in FIG. 2, the X-axis direction intersects with the Z-axis direction, and the Y-axis direction is substantially perpendicular to the plane defined by the X-axis direction and the Z-axis direction.

For example, in a state in which the auxiliary film 180 is disposed on the second adhesive layer 133, the reinforcing substrate 140 can be bonded thereto. Accordingly, an uneven pattern corresponding to the uneven pattern 185 on the lower surface of the auxiliary film 180 can be formed on the upper surface of the second adhesive layer 133.

The concave portion or the convex portion of the uneven pattern 185 can be uniformly disposed, and is not limited thereto, and the concave portion or the convex portion can be randomly disposed. Further, each of the uneven patterns 185 can have different sizes.

As described above, the auxiliary film 180 of the first embodiment of the present disclosure is disposed in the bezel area BA between the reinforcement substrate 140 and the second adhesive layer 133 to suppress the expansion and contraction of the reinforcement substrate 140 in a high temperature and high humidity environment, thereby effectively controlling the generation of diagonal bubbles. Accordingly, it is possible to minimize the interfacial effect due to the expansion and contraction of the reinforcing substrate 140 in a high temperature and high humidity environment and effectively control the generation of bubbles to reduce the rate of moisture penetration introduced through the bubbles to ensure long-term durability and reliability.

Meanwhile, the uneven pattern of the present disclosure can have a semicircular shape, an elliptical shape, or a rectangular shape other than a triangular shape, which will be described in detail with reference to the drawings.

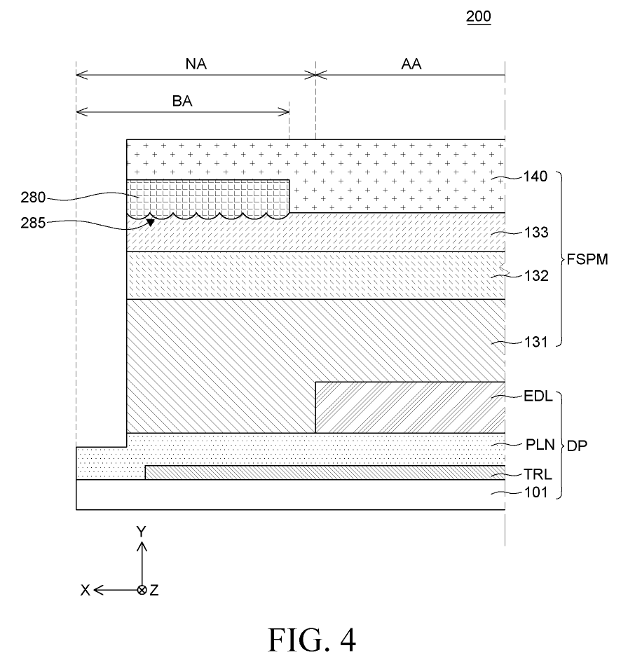

FIG. 4 is a cross-sectional view illustrating a display device according to a second embodiment of the present disclosure.

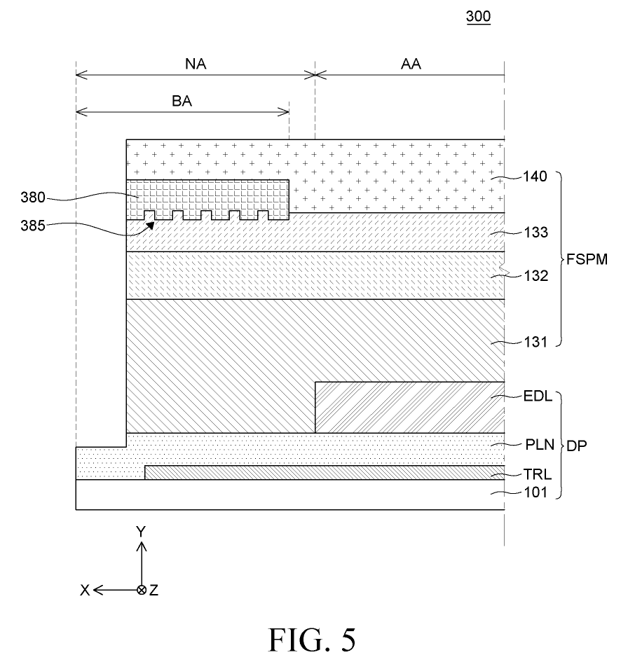

FIG. 5 is a cross-sectional view illustrating a display device according to a third embodiment of the present disclosure.

The only difference or one difference between the display device 200 of the second embodiment and the display device 300 of the third embodiment of the present disclosure in FIGS. 4 and 5 is the shape of the uneven patterns 285 and 385 compared to the first embodiment of the present disclosure in FIGS. 1 to 3 described above, and other configurations are substantially the same, so that a redundant description will be omitted or briefly provided. The same components will be denoted by the same reference numerals. Hereinafter, description of the same reference numerals can be referred to FIGS. 1 to 3.

Referring to FIGS. 4 and 5, the encapsulation part FSPM can be disposed on the display part DP.

The encapsulation part FSPM can include a sealing member 130 and a reinforcing substrate 140.

As described above, the sealing member 130 of the present disclosure can include a first adhesive layer 131 facing the substrate 101, a second adhesive layer 133 facing the reinforcement substrate 140, and a metal layer 132 disposed between the first adhesive layer 131 and the second adhesive layer 133.

Further, in the second and third embodiments of the present disclosure, an auxiliary film 280 and 380 having a low coefficient of thermal expansion is inserted into the bezel area BA where diagonal bubbles are generated due to expansion and contraction of the reinforcing substrate 140 having a high coefficient of thermal expansion to suppress deformation.

The auxiliary films 280 and 380 according to the second and third embodiments of the present disclosure can be formed of a film such as silicon having a low coefficient of thermal expansion.

Further, for example, the auxiliary films 280 and 380 according to the second and third embodiments of the present disclosure can include uneven patterns 285 and 385 on the lower surface thereof in order to enhance interface adhesion. The uneven patterns 285 and 385 can be configured such that concave or convex portions in the form of semicircles or rectangles are repeatedly arranged, and are not limited thereto.

The uneven patterns 285 and 385 can be disposed side by side in one direction. However, the present disclosure is not limited thereto, and the uneven patterns 285 and 385 can be disposed in a zigzag shape in one direction.

An uneven pattern corresponding to the uneven patterns 285 and 385 on the lower surfaces of the auxiliary films 280 and 380 can be formed on the upper surface of the second adhesive layer 133.

Meanwhile, the auxiliary film of the present disclosure can be disposed to extend to a boundary between the display area and the non-display area, which will be described in detail with reference to the drawings.

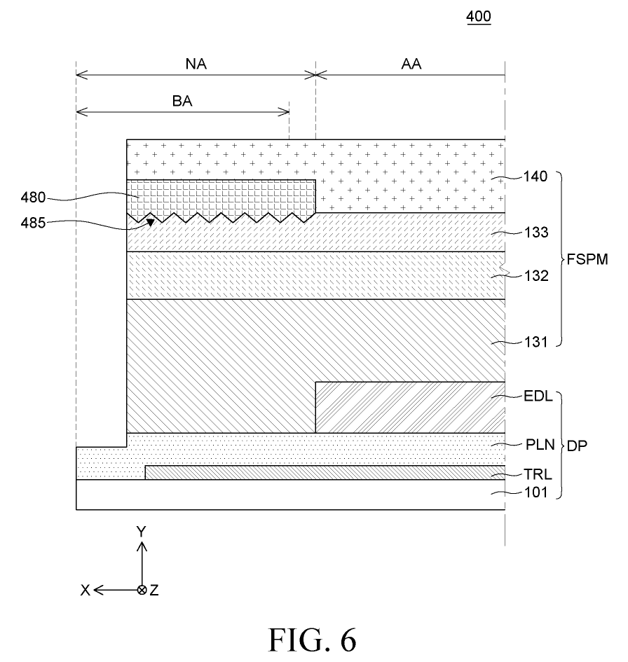

FIG. 6 is a cross-sectional view illustrating a display device according to a fourth embodiment of the present disclosure.

The display device 400 according to the fourth embodiment of the present disclosure shown in FIG. 6 has the substantially same configuration as the first embodiment of the present disclosure shown in FIG. 1 through FIG. 3 described above except for the auxiliary film 480, so that a redundant description will be omitted or briefly provided. The same components will be denoted by the same reference numerals. Hereinafter, description of the same reference numerals can be referred to FIG. 1 through FIG. 5.

Referring to FIG. 6, the encapsulation part FSPM can be disposed on the display part DP.

According to the fourth embodiment of the present disclosure, an auxiliary film 480 having a low coefficient of thermal expansion is inserted into the non-display area NA where diagonal bubbles are generated due to expansion and contraction of the reinforcing substrate 140 having a high coefficient of thermal expansion to suppress deformation.

The auxiliary film 480 according to the fourth embodiment of the present disclosure is characterized in that it extends to the bezel area BA and reaches a boundary between the display area AA and the non-display area NA.

The auxiliary film 480 of the fourth embodiment of the present disclosure can be formed of a film such as silicon having a low coefficient of thermal expansion.

Further, for example, the auxiliary film 480 according to the fourth embodiment of the present disclosure can include the uneven pattern 485 on the lower surface thereof in order to enhance interface adhesion. For example, the uneven pattern 485 can be configured such that concave or convex portions in the form of semicircles, triangles, or rectangles are repeatedly arranged, and is not limited thereto.

The uneven pattern 485 can be disposed side by side in one direction. However, the present disclosure is not limited thereto, and the uneven pattern 485 can be disposed in a zigzag shape in one direction.

Meanwhile, the uneven pattern of the present disclosure can be formed on the upper surface as well as the lower surface of the auxiliary film, which will be described in detail with reference to the drawings.

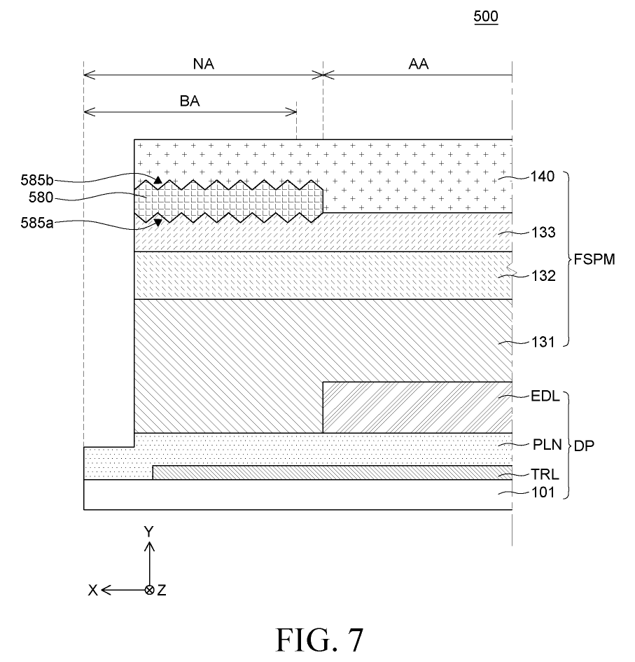

FIG. 7 is a cross-sectional view illustrating a display device according to a fifth embodiment of the present disclosure.

The display device 500 according to the fifth embodiment of the present disclosure of FIG. 7 has the substantially same configuration as the first embodiment of the present disclosure of FIGS. 1 to 3 described above except for the auxiliary film 580, so that a redundant description will be omitted or briefly provided. The same components will be denoted by the same reference numerals. Hereinafter, description of the same reference numerals can be referred to FIG. 1 through FIG. 6.

Referring to FIG. 7, the encapsulation part FSPM can be disposed on the display part DP.

According to the fifth embodiment of the present disclosure, an auxiliary film 580 having a low coefficient of thermal expansion is inserted into the non-display area NA where diagonal bubbles are generated due to expansion and contraction of the reinforcing substrate 140 having a high coefficient of thermal expansion to suppress deformation.

The auxiliary film 580 according to the fifth example embodiment of the present disclosure can extend to the bezel area BA and reach a boundary between the display area AA and the non-display area NA. However, the present disclosure is not limited thereto. A part of the non-display area NA, for example, the bezel area BA can also be covered by the auxiliary film 580.

The auxiliary film 580 of the fifth embodiment of the present disclosure can be formed of a film such as silicon having a low coefficient of thermal expansion.

Further, for example, the auxiliary film 580 of the fifth embodiment of the present disclosure can include uneven patterns 585a and 585b on the lower and upper surfaces thereof in order to enhance interface adhesion. For example, the uneven patterns 585a and 585b can include a first uneven pattern 585a disposed on the lower surface of the auxiliary film 580 and a second uneven pattern 585b disposed on the upper surface of the auxiliary film 580. Further, for example, the uneven patterns 585a and 585b can be configured such that concave or convex portions in the form of semicircles, triangles, or rectangles are repeatedly arranged, and are not limited thereto.

Further, the first uneven pattern 585a and the second uneven pattern 585b can have different shapes. For example, for example, the first uneven pattern 585a can be configured such that concave or convex portions in the form of triangles are repeatedly disposed, and the second uneven pattern 585b can be configured such that concave or convex portions in the form of semicircles or rectangles are repeatedly disposed.

The uneven patterns 585a and 585b can be disposed side by side in one direction. However, the present disclosure is not limited thereto, and the first uneven pattern 585a and the second uneven pattern 585b can be disposed side by side in different directions. For example, the first uneven pattern 585a can be disposed side by side in one direction, and the second uneven pattern 585b can be disposed side by side in another direction perpendicular to one direction. Further, for example, the first uneven pattern 585a and the second uneven pattern 585b can be disposed side by side in opposite directions.

However, the present disclosure is not limited thereto, and the uneven patterns 585a and 585b can be disposed in a zigzag shape in one direction. Further, a zigzag shape of the first uneven pattern 585a and a zigzag shape of the second uneven pattern 585b can coincide with each other or can be staggered with each other.

As described above, in the fifth embodiment of the present disclosure, as the uneven patterns 585a and 585b are formed on the upper surface as well as the lower surface of the auxiliary film 580, it is possible to further minimize the interfacial effect caused by expansion and contraction of the reinforcing substrate 140 even in a high temperature and high humidity environment.

Meanwhile, the auxiliary film of the present disclosure can be disposed not only between the reinforcement substrate and the second adhesive layer, but also between the first adhesive layer and the planarization layer, and this will be described in detail with reference to the drawings.

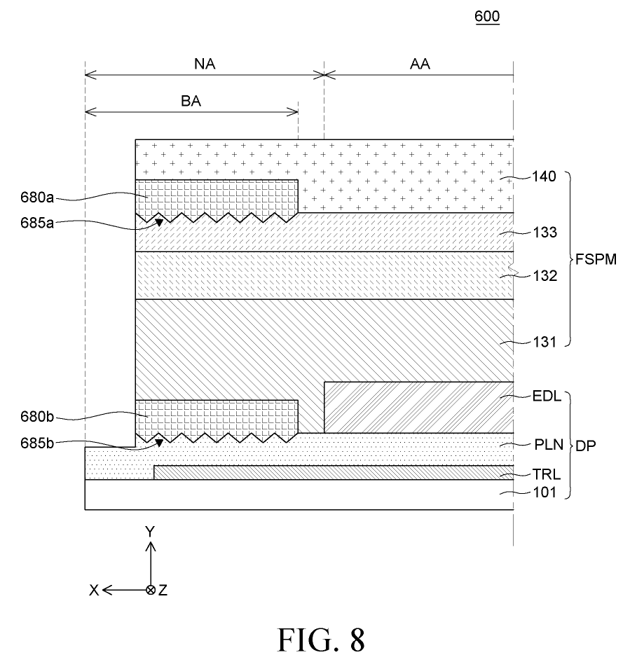

FIG. 8 is a cross-sectional view illustrating a display device according to a sixth embodiment of the present disclosure.

A display device 600 according to the sixth example embodiment of the present disclosure of FIG. 8 has the substantially same configurations as those of the first example embodiment of the present disclosure of FIGS. 1 to 3 described above except for auxiliary films 680a and 680b, so that a redundant description will be omitted or briefly provided. The same components will be denoted by the same reference numerals. Hereinafter, description of the same reference numerals can be referred to FIG. 1 through FIG. 7.

Referring to FIG. 8, the encapsulation part FSPM can be disposed on the display part DP.

According to the sixth embodiment of the present disclosure, the auxiliary films 680a and 680b having a low coefficient of thermal expansion are inserted into the bezel area BA where diagonal bubbles are generated due to the expansion and contraction of the reinforcement substrate 140 having a high coefficient of thermal expansion to suppress the deformation. However, the present disclosure is not limited thereto, and the auxiliary films 680a and 680b can extend to the bezel area BA and reach a boundary between the display area AA and the non-display area NA.

The auxiliary films 680a and 680b can include a first auxiliary film 680a disposed between the reinforcement substrate 140 and the second adhesive layer 133 and a second auxiliary film 680b disposed between the first adhesive layer 131 and the planarization layer PLN. However, the present disclosure is not limited thereto, and an auxiliary film can be added and disposed between the second adhesive layer 133 and the metal layer 132 and/or the metal layer 132 and the first adhesive layer 131. The auxiliary films 680a and 680b can have a rectangular frame shape along the edge of the non-display area NA, and are not limited thereto.

The auxiliary films 680a and 680b according to the sixth embodiment of the present disclosure can be formed of a film such as silicon having a low thermal expansion coefficient.

Further, for example, the auxiliary films 680a and 680b according to the sixth example embodiment of the present disclosure can each include the uneven patterns 685a and 685b on the lower surface thereof in order to enhance interface adhesion. However, the present disclosure is not limited thereto, and the uneven pattern can be added to and provided on the upper surface as well as the lower surfaces of the auxiliary films 680a and 680b.

For example, the uneven patterns 685a and 685b can be configured such that concave or convex portions in the form of semicircles, triangles, or rectangles are repeatedly arranged, and are not limited thereto.

Further, the uneven patterns 685a and 685b can have different shapes. For example, for example, the first uneven pattern 685a of the first auxiliary film 680a can be configured such that concave or convex portions in the form of triangles are repeatedly arranged, while the second uneven pattern 685b of the second auxiliary film 680b can be configured such that concave or convex portions in the form of semicircles or rectangles are repeatedly arranged. Further, on the contrary, the first uneven pattern 685a of the first auxiliary film 680a can be configured such that concave or convex portions in the form of semicircles or rectangles are repeatedly arranged, while the second uneven pattern 685b of the second auxiliary film 680b can be configured such that concave or convex portions in the form of triangles are repeatedly arranged.

The uneven patterns 685a and 685b can be disposed side by side in one direction. However, the present disclosure is not limited thereto, and the first uneven pattern 685a and the second uneven pattern 685b can be disposed side by side in different directions. For example, the first uneven pattern 685a can be disposed side by side in one direction, and the second uneven pattern 685b can be disposed side by side in another direction perpendicular to one direction. Further, for example, the first uneven pattern 685a and the second uneven pattern 685b can be disposed side by side in opposite directions.

However, the present disclosure is not limited thereto, and the uneven patterns 685a and 685b can be disposed in a zigzag pattern in one direction. Further, a zigzag shape of the first uneven pattern 685a and a zigzag shape of the second uneven pattern 685b can coincide with each other or can be staggered with each other.

As described above, in the sixth example embodiment of the present disclosure, as the auxiliary films 680a and 680b are disposed not only between the reinforcement substrate 140 and the second adhesive layer 133 but also between the first adhesive layer 131 and the planarization layer PLN, the influence of the interface due to the expansion and contraction of the reinforcement substrate 140 in a high temperature and high humidity environment can be further minimized.

Meanwhile, the auxiliary film of the present disclosure can have a zigzag shape in one direction, which will be described in detail with reference to the drawings.

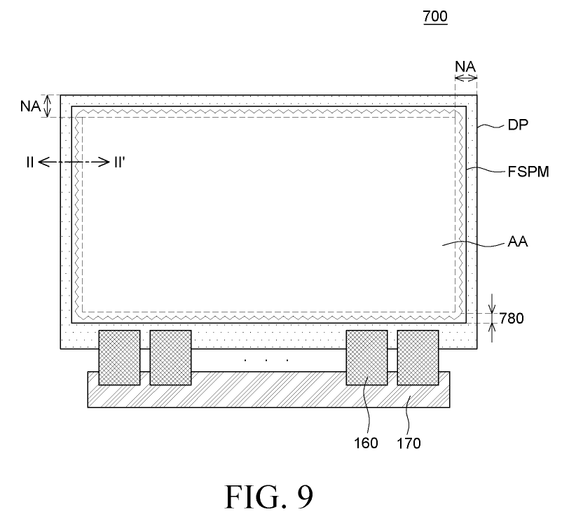

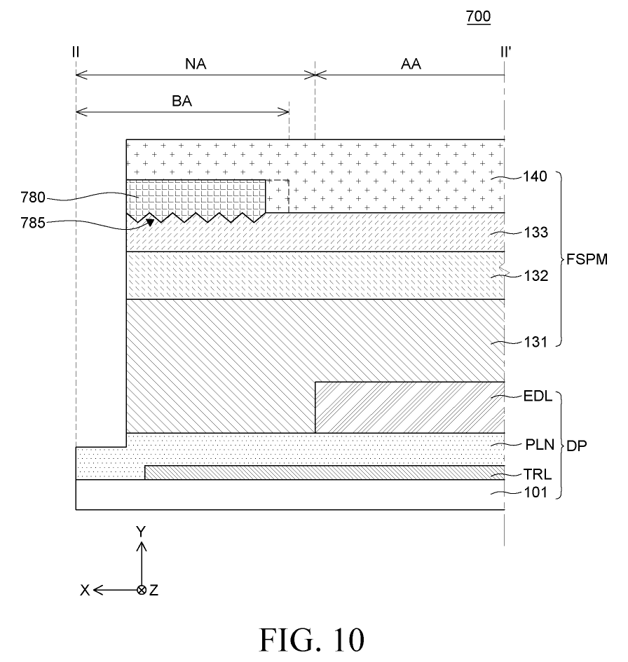

FIG. 9 is a plan view schematically illustrating a display device according to a seventh embodiment of the present disclosure. FIG. 10 is a cross-sectional view taken along the line II-II' of FIG. 9. FIG. 10 illustrates a cross-section of one side of the display device 700 as an example.

In FIG. 10, for the convenience of description, a detailed configuration of the transistor layer TRL and the light emitting element layer EDL is omitted.

The display device 700 according to the seventh embodiment of the present disclosure of FIGS. 9 and 10 has the substantially same configuration as the display device 100 according to the first embodiment of the present disclosure of FIGS. 1 to 3 described above except for the auxiliary film 780, so that a redundant description will be omitted or briefly provided. The same components will be denoted by the same reference numerals. Hereinafter, description of the same reference numerals can be referred to FIGS. 1 to 8.

Referring to FIGS. 9 and 10, the encapsulation part FSPM can be disposed on the display part DP.

According to the seventh example embodiment of the present disclosure, the auxiliary film 780 having a low coefficient of thermal expansion is inserted into the bezel area BA where diagonal bubbles are generated due to the expansion and contraction of the reinforcement substrate 140 having a high coefficient of thermal expansion to suppress the deformation. However, the present disclosure is not limited thereto, and the auxiliary film 780 can extend to the bezel area BA and reach a boundary between the display area AA and the non-display area NA.

The auxiliary film 780 can be disposed between the reinforcement substrate 140 and the second adhesive layer 133, and is not limited thereto. The auxiliary film 780 can be additionally disposed between the first adhesive layer 131 and the planarization layer PLN, the second adhesive layer 133 and the metal layer 132, and/or the metal layer 132 and the first adhesive layer 131. The auxiliary film 780 can have a rectangular frame shape along the edge of the non-display area NA, and is not limited thereto.

The auxiliary film 780 of the seventh embodiment of the present disclosure can be formed of a film such as silicon having a low coefficient of thermal expansion.

Further, for example, the auxiliary film 780 of the seventh example embodiment of the present disclosure can include the uneven pattern 785 on the lower surface thereof to enhance interface adhesion. However, the present disclosure is not limited thereto, and an uneven pattern can be added to and provided on the upper surface as well as the lower surface of the auxiliary film 780.

For example, the uneven pattern 780 can be configured such that concave or convex portions in the form of semicircles, triangles, or rectangles are repeatedly arranged, and is not limited thereto.

The uneven pattern 780 can be disposed side by side in one direction. However, the present disclosure is not limited thereto.

Meanwhile, the auxiliary film 780 according to the seventh embodiment of the present disclosure can have a zigzag shaped inner surface. For example, as shown in FIG. 9, the inner surfaces of the auxiliary film 780 protrude or are recessed at regular intervals in a direction parallel to the data line on the left and right sides of the display part DP, so that the auxiliary film 780 can have a zigzag shape as a whole. On the upper and lower sides of the display part DP, the inner surface of the auxiliary film 780 protrudes or is recessed at regular intervals in a direction parallel to the gate line, and thus, can have a zigzag shape as a whole.

However, the present disclosure is not limited thereto, and the inner surface of the auxiliary film 780 can protrude or be recessed at irregular intervals.

Not only the inner surface but also the outer surface of the auxiliary film 780 can have a zigzag shape. For example, the outer surface of the auxiliary film 780 protrudes or is recessed at regular intervals, so that it can have a zigzag shape as a whole. In this case, the outer surface of the reinforcing substrate 140 disposed thereon can have the same zigzag shape.

As described above, when the inner surface of the auxiliary film 780 has a zigzag shape, expansion and contraction of the reinforcement substrate 140 can be effectively buffered in a high temperature and high humidity environment. For example, the expansion and contraction of the reinforcement substrate 140 in the high temperature and high humidity environment are different along the side surface of the display part DP. When the inner surface of the auxiliary film 780 has a zigzag shape, the deformation of the reinforcement substrate 140 can be more effectively suppressed by flexibly responding to the asymmetric expansion and contraction.

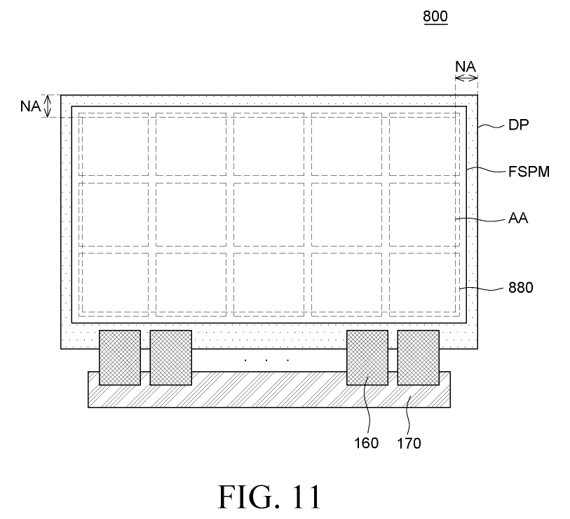

FIG. 11 is a plan view schematically illustrating a display device according to an eighth embodiment of the present disclosure.

The display device 800 according to the eighth example embodiment of the present disclosure of FIG. 11 has the substantially same configuration as the first example embodiment of the present disclosure of FIGS. 1 to 3 described above except for the auxiliary film 880, so that a redundant description will be omitted or briefly provided. The same components will be denoted by the same reference numerals. Hereinafter, description of the same reference numerals can be referred to FIG. 1 through FIG. 10.

Referring to FIG. 11, an encapsulation part FSPM can be disposed on the display part DP.

According to the eighth example embodiment of the present disclosure, an auxiliary film 880 having a low coefficient of thermal expansion is inserted into the non-display area NA and a portion of the display area AA to suppress deformation. For example, the auxiliary film 880 according to the eighth example embodiment of the present disclosure can extend to and be disposed over the bezel area BA (see FIG. 2) as well as the non-display area NA and a part of the display area AA.

In addition, the auxiliary film 880 can be disposed between the reinforcement substrate 140 and the second adhesive layer 133 of FIG. 2, and is not limited thereto as described above.

The auxiliary film 880 according to the eighth example embodiment of the present disclosure can be disposed in a square frame form along the edge of the non-display area NA and a pattern in a matrix form (such as a bridge form, or a checkerboard form) can additionally be provided in the display area AA, and is not limited thereto. For example, since the oblique line defect caused by the difference in the thermal expansion coefficient between the substrate (101 in FIG. 2) and the sealing member (130 in FIG. 2) occurs in the bezel area BA, which is an outer part of the display area AA that displays the screen, the auxiliary film 880 can be disposed in the non-display area NA including the bezel area BA , and, as the area increases, a pattern in a matrix form can additionally be provided within the display area AA to reduce the effect of defects.

The auxiliary film 880 according to the eighth embodiment of the present disclosure can be made of a material having a CTE of 10 ppm or less, such as silicon, tungsten, molybdenum, titanium, and platinum.

Further, for example, the auxiliary film 880 according to the eighth example embodiment of the present disclosure can have an uneven pattern on the lower surface thereof in order to enhance interface adhesion. However, the present disclosure is not limited thereto, and an uneven pattern can be added to and provided on the upper surface as well as the lower surface of the auxiliary film 880.

Further, the auxiliary film 880 according to the eighth embodiment of the present disclosure can have a zigzag shaped inner surface. In addition, not only the inner surface but also the outer surface of the auxiliary film 880 can have a zigzag shape.

The example embodiments of the present disclosure can also be described as follows:

A display device according to an example embodiment of the present disclosure includes a display part including a display area and a non-display area, a sealing member disposed over the display part, a reinforcement substrate disposed over the sealing member, and an auxiliary film disposed between the sealing member and the reinforcement substrate in the non-display area and made of a material having a smaller coefficient of thermal expansion than that of the reinforcement substrate, and having an uneven pattern on a lower surface of the auxiliary film.

The display part can include a transistor layer over the substrate, a planarization layer over the transistor layer, and a light emitting element layer over the planarization layer.

The sealing member can include a first adhesive layer facing the substrate, a second adhesive layer facing the reinforcing substrate, and a metal layer disposed between the first adhesive layer and the second adhesive layer.

The reinforcing substrate can be made of a plastic polymer material.

The auxiliary film can be disposed between the reinforcing substrate and the second adhesive layer.

The auxiliary film can be disposed along an edge of the non-display area to have a rectangular frame shape.

The auxiliary film can be made of a material having a coefficient of thermal expansion of 10 ppm or less.

The uneven pattern can be configured by repeatedly arranging concave or convex portions having a semicircular, elliptical, triangular, or rectangular shape.

The uneven pattern can be disposed side by side in one direction.

The uneven pattern can be disposed in a zigzag shape in one direction.

An uneven pattern corresponding to the uneven pattern of the auxiliary film can be disposed on an upper surface of the second adhesive layer.

The auxiliary film can be disposed from one end of the reinforcement substrate to a boundary between the display area and the non-display area.

The display device can further include an additional uneven pattern formed on an upper surface of the auxiliary film.

The uneven pattern and the additional uneven pattern can have different shapes.

The uneven pattern and the additional uneven pattern can be disposed side by side in different directions.

The uneven pattern and the additional uneven pattern can be disposed in a zigzag shape in one direction.

The display device can further include an additional auxiliary film disposed between the first adhesive layer and the planarization layer, between the second adhesive layer and the metal layer, and/or between the metal layer and the first adhesive layer, and an additional uneven pattern provided on a lower surface of the additional auxiliary film.

The auxiliary film can have a zigzag shaped inner surface.

On first opposite sides (e.g., left and right sides) of the display part, an inner surface of the auxiliary film can be alternately protruded or recessed at regular intervals in a direction parallel to a data line, forming a zigzag shape as a whole. Further, on second opposite sides (e.g., upper and lower sides) of the display part, the inner surface of the auxiliary film can be alternately protruded or recessed at regular intervals in a direction parallel to a gate line, forming a zigzag shape as a whole.

The auxiliary film and the reinforcing substrate can have a zigzag shaped outer surface.

Although the example embodiments of the present disclosure have been described in detail with reference to the accompanying drawings, the present disclosure is not limited thereto and can be embodied in various forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a display part including a display area and a non-display area;
a sealing member disposed over the display part;
a reinforcement substrate disposed over the sealing member; and
an auxiliary film disposed between the sealing member and the reinforcement substrate in the non-display area, and made of a material having a smaller coefficient of thermal expansion than that of the reinforcement substrate, the auxiliary film having an uneven pattern on a lower surface of the auxiliary film.

2. The display device according to claim 1, wherein the display part includes:
a transistor layer disposed over a substrate;
a planarization layer disposed over the transistor layer; and
a light emitting element layer disposed over the planarization layer.

3. The display device according to claim 2, wherein the sealing member includes:
a first adhesive layer facing the substrate;
a second adhesive layer facing the reinforcing substrate; and
a metal layer disposed between the first adhesive layer and the second adhesive layer.

4. The display device according to claim 3, wherein the reinforcing substrate includes a plastic polymer material.

5. The display device according to claim 3, wherein the auxiliary film is disposed between the reinforcement substrate and the second adhesive layer.

6. The display device according to claim 1, wherein the auxiliary film is disposed along an edge of the non-display area to have a rectangular frame shape.

7. The display device according to claim 1, wherein the auxiliary film includes a material having a coefficient of thermal expansion of 10 ppm or less.

8. The display device according to claim 1, wherein the uneven pattern of the auxiliary film is configured by repeatedly arranging concave or convex portions having a semicircular, elliptical, triangular, or rectangular shape.

9. The display device according to claim 1, wherein the uneven pattern of the auxiliary film is disposed side by side in one direction.

10. The display device according to claim 1, wherein the uneven pattern of the auxiliary film is disposed in a zigzag shape in one direction.

11. The display device according to claim 3, wherein an uneven pattern corresponding to the uneven pattern of the auxiliary film is disposed over an upper surface of the second adhesive layer.

12. The display device according to claim 1, wherein the auxiliary film is disposed from one end of the reinforcement substrate to a boundary between the display area and the non-display area.

13. The display device according to claim 1, further comprising:
an additional uneven pattern disposed over an upper surface of the auxiliary film.

14. The display device according to claim 13, wherein the uneven pattern and the additional uneven pattern have different shapes.

15. The display device according to claim 13, wherein the uneven pattern and the additional uneven pattern are disposed side by side in different directions.

16. The display device according to claim 13, wherein the uneven pattern and the additional uneven pattern are disposed in a zigzag shape in one direction.

17. The display device according to claim 3, further comprising:
an additional auxiliary film disposed between the first adhesive layer and the planarization layer, between the second adhesive layer and the metal layer and/or between the metal layer and the first adhesive layer; and
an additional uneven pattern provided on a lower surface of the additional auxiliary film.

18. The display device according to claim 1, wherein the auxiliary film has a zigzag shaped inner surface.

19. The display device according to claim 18, wherein on first opposite sides of the display part, an inner surface of the auxiliary film is alternately protruded or recessed at regular intervals in a direction parallel to a data line, forming a zigzag shape as a whole, and
wherein on second opposite sides of the display part, the inner surface of the auxiliary film is alternately protruded or recessed at regular intervals in a direction parallel to a gate line, forming a zigzag shape as a whole.

20. The display device according to claim 18, wherein the auxiliary film and the reinforcing substrate have a zigzag shaped outer surface.
